(19) United States
(12) Patent Application Publication
(10) Pub. No.: US 2026/0281578 A1
(43) Pub. Date: Sep. 17, 2026

(54) IN-SENSOR MULTIPLY-AND-ACCUMULATE PIXEL SENSOR CIRCUIT ASSEMBLY

(71) Applicant: University of Tennessee Research Foundation, Knoxville, TN (US)

(72) Inventors: Ahmedullah Aziz, Knoxville, TN (US); Md Rahatul Islam Udoy, Knoxville, TN (US)

(21) Appl. No.: 19/555,078

(22) Filed: Mar. 3, 2026

Related U.S. Application Data
(60) Provisional application No. 63/766,135, filed on Mar. 3, 2025.

(51) Int. Cl. H04N 25/77; H04N 25/766; H10F 39/00

(52) U.S. Cl. CPC H04N 25/77; H04N 25/766; H10F 39/811

(57) ABSTRACT

An in-sensor multiply-and-accumulate (MAC) pixel sensor circuit assembly for employment in automotive, aerospace, medical, robotics, industrial, civilian, and military applications, among many other possibilities. The in-sensor multiply-and-accumulate pixel sensor circuit assembly, per an implementation, includes a multitude of transistors and a ferroelectric field-effect transistor (FeFET). Multidomain polarization states of the FeFET are leveraged in order to perform multiply-and-accumulate operations amid use of the in-sensor multiply-and-accumulate pixel sensor circuit assembly. Real-time edge computing, neuromorphic vision, and secure sensing are examples of applications in which the in-sensor multiply-and-accumulate pixel sensor circuit assembly is well suited.

### CROSS-REFERENCE TO RELATED APPLICATION

This application claims the benefit of U.S. Provisional Patent Application No. 63/766,135, with a filing date of Mar. 3, 2025, the contents of which are hereby incorporated by reference in their entirety.

### TECHNICAL FIELD

The present disclosure relates generally to image sensors and, more particularly, to pixel circuit configurations employed in image sensors.

### BACKGROUND

Image sensors are semiconductor devices that convert optical images into digital signals. Multiply-and-accumulate (MAC) is a fundamental operation in computing that, in general, performs weighted summations that are important for signal processing and machine learning, among other applications. MAC is a core operation in early-stage vision processing, underpinning a first layer of convolutional neural networks (CNNs). Moreover, in-sensor MAC execution in which computations are embedded and occur directly within the sensor has proven particularly beneficial. It eliminates the need to transfer an entire raw fame off-chip, significantly reducing data movement and enabling faster and more energy-efficient operations.

Applications in which in-sensor MAC operations are sought include real-time edge computing, neuromorphic vision, secure sensing implementations, edge artificial intelligence (AI), always-on object detection, face authentication, smart home monitoring, autonomous driving, driver monitoring, wearable activity recognition, industrial defect classification, privacy-preserving surveillance, ultra-low-power wake-up cameras, among many other possibilities. Moreover, fields in which in-sensor MAC operations can be useful include, but are not limited to, automotive, aerospace, medical, robotics, civilian, and military fields.

But past efforts in implementing MAC operations in-sensor and at the pixel level remain challenged with an inability to concurrently deliver compactness in design and construction, low power consumption, and non-volatile weight storage, among other shortcomings. These drawbacks, as well as others, have largely precluded scalability in the previous in-sensor MAC operation efforts.

### SUMMARY

In an embodiment, an in-sensor multiply-and-accumulate (MAC) pixel sensor circuit assembly for employment in an image sensor may include a first transistor and a ferroelectric field-effect transistor (FeFET). The first transistor and the ferroelectric field-effect transistor are electrically coupled with each other. During use of the in-sensor multiply-and-accumulate pixel sensor circuit assembly, a programming voltage amplitude of the ferroelectric field-effect transistor is varied in order to effect various levels of remnant polarizations of the ferroelectric field-effect transistor. As a result, variations in conductance are provided of the ferroelectric field-effect transistor.

In an embodiment, an in-sensor multiply-and-accumulate (MAC) pixel sensor circuit assembly for employment in an image sensor may include a first transistor, a ferroelectric field-effect transistor (FeFET), and a pixel selector transistor. The first transistor and the ferroelectric field-effect transistor are electrically coupled with each other, and the first transistor and the pixel selector transistor are electrically coupled with each other. During use of the in-sensor multiply-and-accumulate pixel sensor circuit assembly, multiply-and-accumulate operations of the in-sensor multiply-and-accumulate pixel sensor circuit assembly are executed wholly at the in-sensor multiply-and-accumulate pixel sensor circuit assembly itself. Further, during use of the in-sensor multiply-and-accumulate pixel sensor circuit assembly, amid a reset phase of an active weight cycle of the in-sensor multiply-and-accumulate pixel sensor circuit assembly, a negative gate pulse is applied to the ferroelectric field-effect transistor in order to reset the ferroelectric field-effect transistor. Subsequently, amid the reset phase, a positive gate pulse is applied to the ferroelectric field-effect transistor in order to set a polarization amount of the ferroelectric field-effect transistor. Yet further, during use of the in-sensor multiply-and-accumulate pixel sensor circuit assembly, amid an inactive weight cycle of the in-sensor multiply-and-accumulate pixel sensor circuit assembly, the ferroelectric field-effect transistor is deactivated.

In an embodiment, an in-sensor multiply-and-accumulate (MAC) pixel sensor circuit assembly for employment in an image sensor may include a first transistor, a ferroelectric field-effect transistor (FeFET), and a pixel selector transistor. The first transistor and the ferroelectric field-effect transistor are electrically coupled with each other, and the first transistor and the pixel selector transistor are electrically coupled with each other. A terminal of the ferroelectric field-effect transistor transfers a polarization charge value of the ferroelectric field-effect transistor. During use of the in-sensor multiply-and-accumulate pixel sensor circuit assembly, multiply-and-accumulate operations of the in-sensor multiply-and-accumulate pixel sensor circuit assembly are executed wholly at the in-sensor multiply-and-accumulate pixel sensor circuit assembly itself. Further, during use of the in-sensor multiply-and-accumulate pixel sensor circuit assembly, a programming voltage amplitude of the ferroelectric field-effect transistor is varied in order to effect various levels of remnant polarizations of the ferroelectric field-effect transistor. As a result, variations in conductance are provided of the ferroelectric field-effect transistor.

Further scope of applicability of the present disclosure will become apparent from the detailed description given hereinafter. But it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given below and the accompanying drawings, which are given by way of illustration only, and do not limit the present disclosure, and wherein:

FIG. 1 is a schematic depiction of an embodiment of a camera and an image sensor having a pixel circuit;

FIG. 2 is a schematic demonstration of a functionality of an embodiment of an in-sensor multiply-and-accumulate (MAC) pixel sensor circuit assembly set forth herein (denoted “MACPIX Sensor Array” in the figure);

FIG. 3 is a schematic demonstration of transmissions between a past pixel array (denoted “Regular Pixel Array” in the figure) and downstream convolutional neural network (CNN) layers, and between the in-sensor MAC pixel sensor circuit assembly (denoted “MACPIX Array (1^{st} CNN Layer)” in the figure) and downstream CNN layers;

FIG. 4A is a schematic depiction of an HfO₂-based ferroelectric field-effect transistor (FeFET) structure;

FIG. 4B is a schematic diagram of a circuit symbol for the FeFET;

FIG. 4C is a graph demonstrating multi-domain FeFET characteristics showing various remnant polarizations (P_{R}) for different programming voltage levels (V_{PR});

FIG. 4D is a schematic diagram of a circuit symbol for a basic 3-transistor (3-T) pixel circuit, in which X_{R} is a reset transistor, X_{SF} is a source-follower transistor, and X_{SEL} is a pixel selector transistor;

FIG. 4E is a timing diagram of the 3-T pixel circuit, where an operational cycle is divided into three phases: light integration phase T_{INT}, readout phase T_{RD}, and reset phase T_{R};

FIG. 5A is a schematic diagram of an embodiment of the in-sensor MAC pixel sensor circuit assembly;

FIG. 5B is a schematic diagram of an embodiment of a ferroelectric field-effect transistor (FeFET) that is incorporated into the in-sensor MAC pixel sensor circuit assembly of FIG. 5A;

FIG. 5C is a timing diagram of the in-sensor MAC pixel sensor circuit assembly, with the FeFET programmed in a photodiode reset phase;

FIG. 5D is an enlargement of a section of the timing diagram of FIG. 5C showing an X_{FE} gate voltage during active weight cycle (AWC) and inactive weight cycle (IWC);

FIG. 5E is an enlargement of another section of the timing diagram of FIG. 5C showing a conductance of Branch_{mod} during active weight cycle (AWC) and inactive weight cycle (IWC);

FIG. 5F is a graph presenting conductance of the FeFET at different programming voltage amplitudes (PVA) and varied HfO₂ thickness;

FIG. 6A is a graph presenting conductance modulation by both a programming voltage amplitude (PVA) and ΔV_{Ph}, where the range of PVA (1.5V to 2.8V) is set by a selected region of FIG. 5D; curves in the graph shift upward with increasing PVA values;

FIG. 6B is a two-dimensional (2D) color map of the true mathematical products of varying PVA and ΔV_{Ph} values; for consistent comparisons, the product values are normalized by their maximum;

FIG. 6C is a 2D color map of pixel currents by exciting the pixel circuit with varying PVA and ΔV_{Ph} values;

FIG. 6D presents the absolute difference between the color maps of FIGS. 6B and 6C, showing error between true and circuit generated product;

FIG. 7A is a schematic diagram of an embodiment of a pixel array configuration of the in-sensor MAC pixel sensor circuit assembly, where all pixel outputs in a column are connected and their output currents are summed to form a column current (L_{out,cn}); all the column currents meet at node NA; three lines (L1, L2, and L3) are used to supply X_{FE} gate signals and the array can handle 3×3 kernel size;

FIG. 7B is a schematic diagram of an embodiment of a simplified conductance model, where each line represents the conductance of a Branch_{mod} of a corresponding pixel;

FIG. 7C shows activation of a 3×3 pixel block corresponding to a kernel position;

FIG. 7D presents an example kernel consisting of both positive and negative weights;

FIG. 7E presents weight assignments to weight lines (L1, L2, and L3) during a positive cycle, where only pixels corresponding to positive weights are activated;

FIG. 7F presents weight assignments to the weight lines (L1, L2, and L3) during a negative cycle, where only pixels corresponding to negative weights are activated;

FIG. 7G presents new weight assignments as the kernel slides to the right with stride=1 during the positive cycle;

FIG. 7H presents new weight assignments as the kernel slides to the right with stride=1 during the negative cycle;

FIG. 7I presents new weight assignments as the kernel slides to the next row—after completion of the first row—during the positive cycle;

FIG. 7J presents new weight assignments as the kernel slides to the next row—after completion of the first row—during the negative cycle;

FIG. 7K is a schematic depiction of an embodiment of a tiled region of a pixel array layout showing horizontal and vertical pixel pitch measurements;

FIG. 7L is a schematic depiction of an embodiment of a layout of a single pixel (i.e., the in-sensor MAC pixel sensor circuit assembly);

FIG. 7M is a schematic depiction of an embodiment of a peripheral circuit used to generate ReLU outputs;

FIG. 8 is a table (TABLE I) of a summary of extracted results from the pixel array layout of FIG. 7K;

FIG. 9A presents a Monte Carlo Simulation-based process variation analysis of the FeFET conductance;

FIG. 9B presents a Monte Carlo Simulation-based process variation analysis of the FeFET polarization;

FIG. 10 is a table (Table II) of sample results for one convolution output element for a certain kernel position;

FIG. 11 is a table (Table III) of a Monte Carlo Simulation; and

FIG. 12 is a table (Table IV) of benchmarking of an embodiment of the in-sensor MAC pixel sensor circuit assembly (denoted “This work” in the table) and past MAC operation arrangements (denoted “[5],” “[12],” “[1],” and “[15]” in the table).

### DETAILED DESCRIPTION

Referring generally to the drawings, an embodiment of an in-sensor multiply-and-accumulate (MAC) pixel sensor circuit assembly or configuration 10 is depicted in the figures and described herein. In general, the in-sensor MAC pixel sensor circuit assembly 10 executes a multiply-and-accumulate operation and process in-sensor and at a pixel-level amid its use, and is implemented in an image sensor and chip 12. Unlike past in-sensor MAC operation arrangements, the in-sensor MAC pixel sensor circuit assembly 10 herein is equipped with a ferroelectric field-effect transistor (FeFET) 14 in its design and construction, serving to enable an in-sensor MAC operation module for some or all of numerous individual pixels 16 in the larger assembly and installation. In other words, the in-sensor MAC pixel sensor circuit assembly 10 is FeFET-based. A multi-domain polarization property of the FeFET 14 is leveraged in the design and construction and operation of the in-sensor MAC pixel sensor circuit assembly 10. Compared to past in-sensor MAC operation arrangements, the in-sensor MAC pixel sensor circuit assembly 10 provides a circuit configuration and pixel architecture that concurrently delivers a simple and compact construction, non-volatility, low power consumption, and minimal transistor count, among other advancements-all ultimately furnishing a scalable in-sensor MAC pixel sensor circuit assembly and design. Overall, a more effective and efficient in-sensor MAC pixel sensor circuit assembly is furnished.

Applications of use include real-time edge computing, neuromorphic vision, secure sensing implementations, edge artificial intelligence (AI), always-on object detection, face authentication, smart home monitoring, autonomous driving, driver monitoring, wearable activity recognition, industrial defect classification, privacy-preserving surveillance, ultra-low-power wake-up cameras, among many other possibilities. And fields in which event detection is often sought include, but are not limited to, automotive, aerospace, medical, robotics, civilian, and military fields. Still, a particular embodiment of the in-sensor MAC pixel sensor circuit assembly 10 may exhibit only one, all, or a combination of, the advancements set forth herein, none of the advancements, or yet other advancements unmentioned.

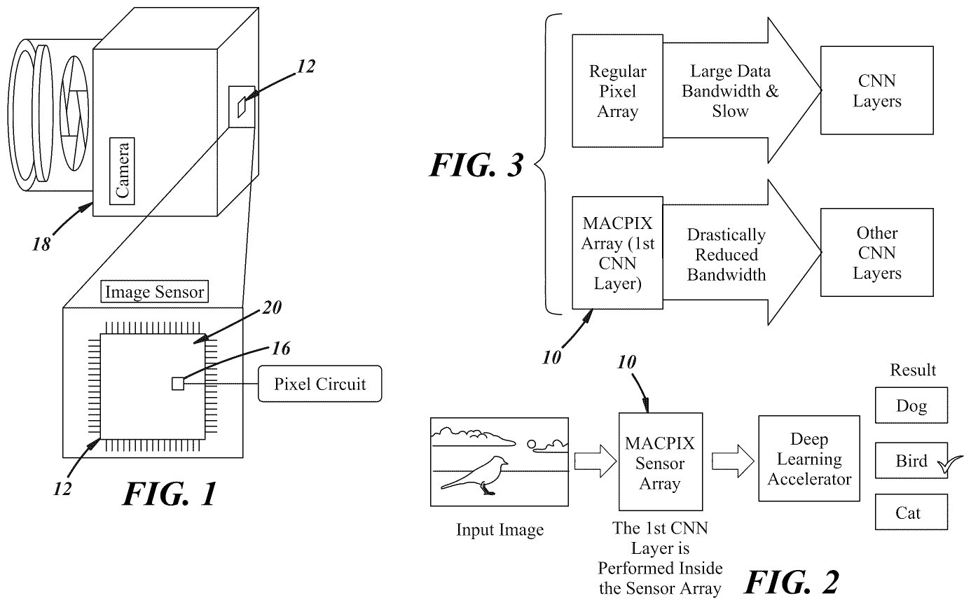

With reference to FIG. 1, an embodiment of the image sensor 12 is presented. The image sensor 12 can be equipped in a camera 18, per an example implementation. A pixel array 20 of the image sensor 12 is made-up of a multitude of the individual pixels 16 arranged in horizontal rows and vertical columns relative to one another; still, other arrangements of pixels are possible. Each of the pixels 16 can be equipped with a dedicated in-sensor MAC pixel sensor circuit assembly 10. In this sense, the term “in-sensor” is intended to mean that the design, construction, and components of the in-sensor MAC pixel sensor circuit assembly 10 are incorporated and located within each of the pixels 16. In other words, the in-sensor MAC pixel sensor circuit assembly 10 resides physically within a boundary of its associated and respective pixel 16, and hence the accompanying MAC operation is executed wholly within that pixel 16. A pixel-level MAC processing circuit is thereby furnished. All of the pixels 16 in the pixel array 20 can have the in-sensor MAC pixel sensor circuit assembly 10, per an embodiment, or only some of the pixels 16 in the pixel array 20 can have the in-sensor MAC pixel sensor circuit assembly 10. Locating the in-sensor MAC pixel sensor circuit assembly 10 in-sensor and in-pixel has been shown to partly or more contribute to one or more of the following advancements: i) simpler and more compact design and construction, ii) increased processing speed, iii) decreased power consumption, iv) enhanced computational efficiencies, and v) decreased geometric area; still, other advancements can arise from the in-sensor location.

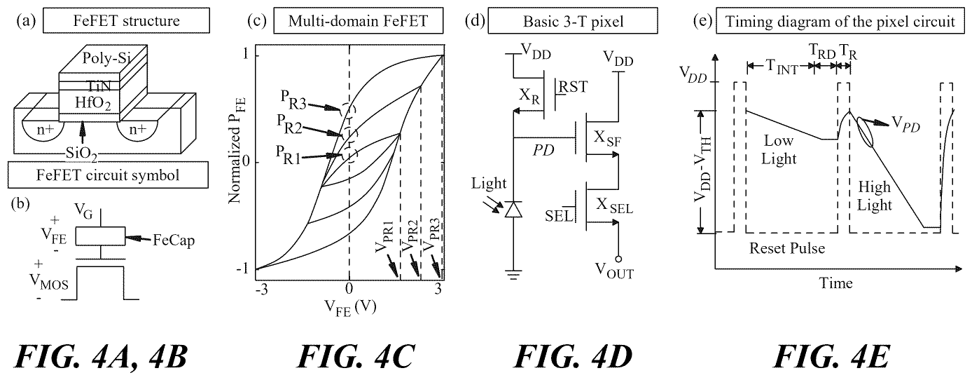

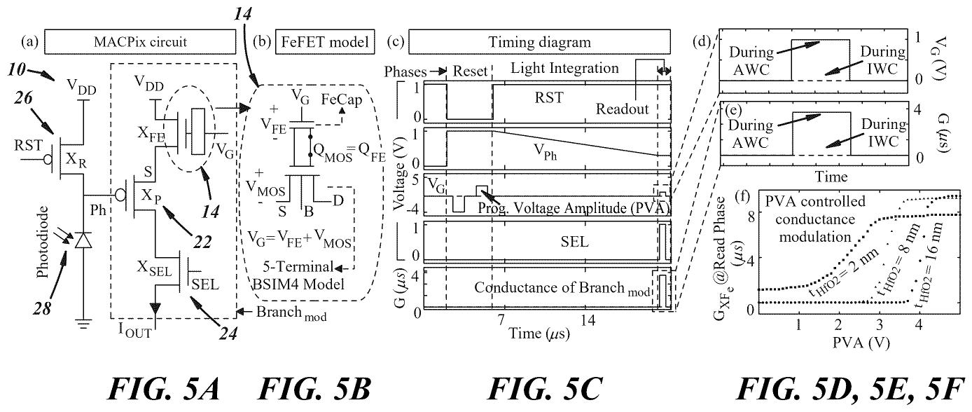

With reference now to FIG. 2, a schematic demonstration of a functionality of the in-sensor MAC pixel sensor circuit assembly 10 is presented. An input image, in this example that of a bird, is received by the pixel array 20 and the numerous in-sensor MAC pixel sensor circuit assemblies 10 (denoted “MACPIX Sensor Array” in the figure). A first convolutional neural network (CNN) layer is performed inside of the pixel array 20, which are then received by a deep learning accelerator for a result “Bird.” Referring now to FIG. 3, it shows a schematic demonstration of transmissions between a past pixel array (denoted “Regular Pixel Array” in the figure) and associated and downstream CNN layers, and between the in-sensor MAC pixel sensor circuit assembly 10 (denoted “MACPIX Array (1^{st} CNN Layer)” in the figure) and associated and downstream CNN layers. The past pixel array is shown to transmit large data bandwidth to the CNN layers and has proven slow. The in-sensor MAC pixel sensor circuit assembly 10, on the other hand, transmits a measurably reduced bandwidth and is hence much faster.

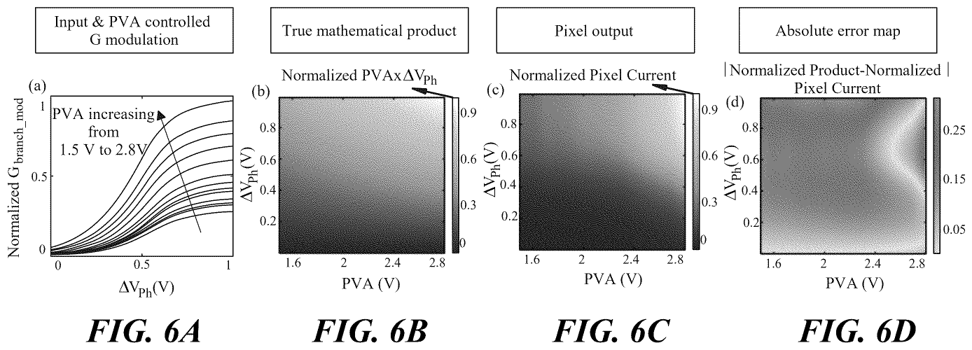

In general, a ferroelectric field-effect transistor (FeFET) is a type of non-volatile transistor that incorporates a ferroelectric capacitor (FeCap) into a gate stack of a MOSFET structure. FIG. 4A shows an FeFET structure where HfO₂ is used as an FeCap. A feature of a ferroelectric material is its ability to retain spontaneous polarization even after the removal of an applied electric field, and this polarization is called the remnant polarization (P_{R}). When programmed with a suitable gate voltage pulse, the remnant polarization of the FeCap modulates the channel conductivity. FeFETs offer CMOS compatibility, which makes them suitable for integration in advanced computing architectures. In compute-in-memory (CiM), FeFET arrays (crossbars) store coefficients or patterns and execute in-memory operations, whereas in compute-in-sensor (CiS)—as set forth herein in the in-sensor MAC pixel sensor circuit assembly 10—computation is co-located with the pixel array and operates directly on photodiode signals. While conventional FeFETs operate with binary polarization states, recent advancements in material engineering have enabled multi-domain behavior within the ferroelectric layer. In multi-domain FeFETs, the polarization is distributed among multiple nanoscale domains that can be partially switched. This allows for multiple stable intermediate polarization levels, resulting in a quasi-analog modulation of the channel conductance. FIG. 4C shows the characteristics of a multidomain FeFET, where for different programming voltages (V_{PR1}, V_{PR2}, and V_{PR3}), different remnant polarizations (P_{R1}, P_{R2}, and P_{R3}) are achieved.

In general, the core component of an image sensor chip is a 2D pixel array. Each unit of this array is commonly built using a 3-transistor (3T) pixel circuit (FIG. 4D). This configuration includes a reverse-biased photodetector along with three transistors: X_{R}, X_{SF}, and X_{SEL}, which function as the reset, source follower, and pixel selector transistors, respectively. The operation sequence for this circuit is depicted in FIG. 4E. The process begins with activating the reset transistor (X_{R}), which initializes the photodetector (PD) node voltage (V_{PD}) to V_{DD}−V_{TH,XR} (here V_{TH,XR} is the threshold voltage of X_{R}). Alternatively, implementing a PMOS transistor for reset allows the PD node to be fully charged to a supply voltage V_{DD}. Following the reset phase, the light integration phase starts as the reset transistor is turned off. During this period, the voltage at the PD node gradually drops due to the photocurrent generated by incident light, as described by the equation: dv/dt=I_{PD}/C_{PD}. Here, I_{PD} represents the photocurrent, and C_{PD} denotes the intrinsic capacitance of the photodiode. Under higher illumination, I_{PD} increases, leading to a more rapid decline in V_{PD} as illustrated during the second cycle in FIG. 4E. The transistor X_{SF} transmits the signal from the photodiode node while preserving the accumulated charge. Meanwhile X_{SEL} serves as a pixel selector. The output of this 3T pixel circuit is denoted by V_{OUT}. In a current mode pixel circuit, the output is a current.

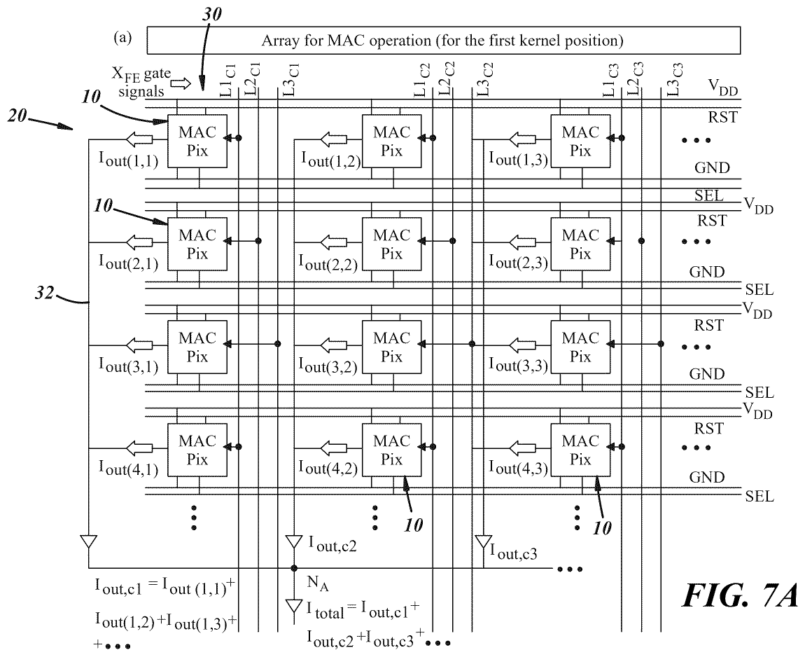

The in-sensor MAC pixel sensor circuit assembly 10 can have various designs, constructions, and components in various embodiments. In the embodiment of FIG. 5A, the in-sensor MAC pixel sensor circuit assembly 10 includes the FeFET 14, a first transistor 22, a second or pixel selector transistor 24, a third or reset transistor 26, and a photodiode 28; still, the in-sensor MAC pixel sensor circuit assembly 10 could have more, less, and/or different components in different embodiments. In implementation, the components of the in-sensor MAC pixel sensor circuit assembly 10 can reside on one or more substrates and possess electrical communication and coupling with one another. According to the embodiment of FIG. 5A, the first transistor 22 and reset transistor 26 are in immediate electrical communication and coupling with each other; the first transistor 22 and pixel selector transistor 24 are in immediate electrical communication and coupling with each other; and the first transistor 22 and FeFET 14 are in immediate electrical communication and coupling with each other.

In order to enable efficient in-sensor computation for edge intelligence applications, the in-sensor MAC pixel sensor circuit assembly 10 employs a pixel architecture that integrates computing capabilities directly into the image sensor array. The in-sensor MAC pixel sensor circuit assembly 10, termed MACPix in certain figures, introduces the FeFET 14 into its pixel design to enable in-sensor analog computation. This modification leverages the multi-domain polarization property of FeFETs (i.e., of the FeFET 14). As shown in FIG. 5A, in the in-sensor MAC pixel sensor circuit assembly 10, an n-type FeFET is connected in series with the source terminal of a PMOS (X_{P}) (i.e., the first transistor 22) of the basic 3T pixel circuit. By varying the programming voltage amplitude (PVA) of the FeFET 14, different levels of remnant polarization (P_{R}) can be effected, resulting in corresponding variations in its conductance. In this embodiment, the FeFET 14 functions as a source degeneration element for the first transistor 22 (X_{P}), and this pixel generates current (I_{OUT}) as an output.

Operation of the in-sensor MAC pixel sensor circuit assembly 10 was simulated in the simulation software known as HSPICE. The multi-domain FeCap model was used, which has been calibrated to experimental ferroelectric data and shown to capture the key switching and polarization behaviors relevant to FeFET operation. To transfer the charge value (Q), both the FeCap and the MOSFET models include an additional terminal, as shown in FIG. 5B. This additional terminal is suitable for the FeFET 14 in order to couple the ferroelectric polarization charge with the channel current of the MOSFET, thereby enabling accurate representation of the multi-domain FeFET behavior. The extra terminal is used to pass the value of charge. Except for the FeFET 14 (X_{FE}), all other transistors (i.e., first, second, and third transistors 22, 24, 26) in the circuit are modeled using standard 4-terminal MOSFET models, according to this embodiment. In the embodiment of FIG. 5B, the FeFET 14 exhibits a modified 5-terminal MOSFET and an HfO₂-based FeCap. The 5-terminals include a first terminal, a second terminal, a third terminal, a fourth terminal, and a fifth terminal. The simulations were carried out using 45 nm high-performance CMOS parameters based on what-is-known-as the Predictive Technology Model, which have been widely validated and are regarded as faithful representations of experimentally measured device characteristics. The transistors have a channel length of 100 nm and a width of 200 nm, according to this example.

### Multiplication

The functionality of the in-sensor MAC pixel sensor circuit assembly 10 is demonstrated in the timing diagram of FIG. 5C. Two types of cycles are defined: an active weight cycle (AWC) and an inactive weight cycle (IWC). A pixel circuit goes through either AWC or IWC. Their differences and purposes are described below. First, the AWC is described. It can be divided into three phases: reset, light integration, and readout phases. In the reset phase, the X_{R} PMOS (i.e., reset transistor 26) is activated and turned on, and the photodiode node voltage (V_{Ph}) reaches V_{DD}. Further, in the reset phase, the programming of the FeFET 14 is carried out: at first a negative gate pulse is applied to reset the FeFET 14 to the outer hysteresis loop, then a positive gate pulse is applied to set a certain amount of polarization, and this programming voltage amplitude (PVA) determines the amount of polarization and corresponding conductance that will be stored in the FeFET 14. In this embodiment of the in-sensor MAC pixel sensor circuit assembly 10, this PVA is applied at a level higher and greater in value than V_{DD}, so that a sufficient V_{GS} is established across the ferroelectric stack (V_{GS}=PVA−V_{S}, where V_{S}<1). This ensures polarization switching and allows the programmed conductance state of the FeFET 14 to be retained for the subsequent phases of operation of the in-sensor MAC pixel sensor circuit assembly 10. Here, the negative and positive pulses applied to the gate of the FeFET 14 during the reset phase will not be required in subsequent cycles unless the stored polarization level needs to be changed.

Furthermore, in the light integration phase of the in-sensor MAC pixel sensor circuit assembly 10, the V_{Ph} starts to drop due to photocurrent generation in the photodiode 28 via incident light levels thereat. The amount of voltage drop (ΔV_{Ph}=V_{DD}−V_{Ph}) is proportional to the incident light level and intensity. At the end of the light integration phase, the pixel selector transistor 24 (X_{SEL}) and X_{FE} are activated and turned on. The PVA of the reset phase directly modulates the polarization of the FeFET 14, thus affecting the conductance of this device. To find the proper region of that modulation, both the thickness of the FeCap and the PVA were varied, as shown in FIG. 5F. Based on this analysis, a FeCap thickness of 2 nm and a PVA range of 1.5 V to 2.8 V was utilized for subsequent simulations; still, other parameters are possible. The branch of this particular circuit is deemed Branch_{mod}, as shown in FIG. 5A. The Branch_{mod} per this embodiment includes the FeFET 14 (X_{FE}), the first transistor 22 (X_{P}), and the pixel selector transistor 24 (X_{SEL}). The conductance of this branch during the readout phase is termed G_{branch_mod}.

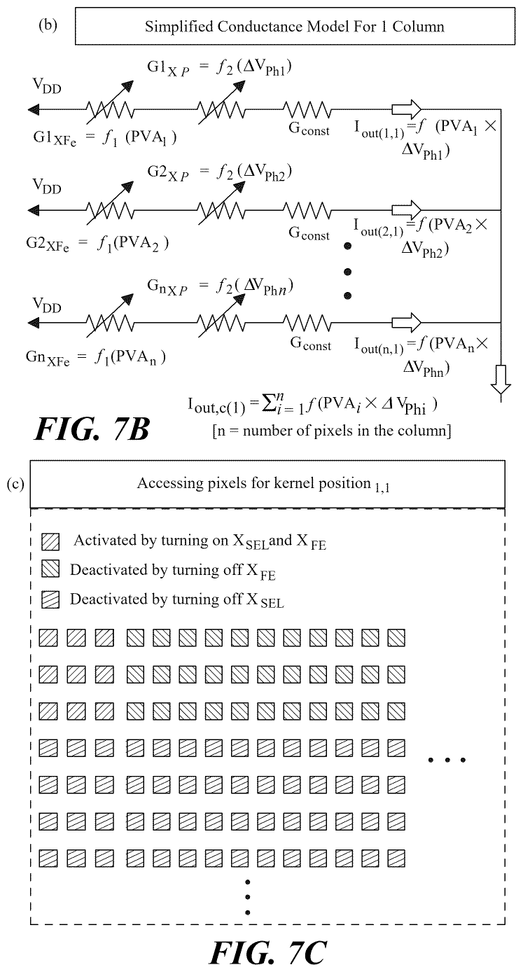

Now, the IWC is described. Amid this whole cycle, the FeFET 14 (X_{FE}) is deactivated and turned off (FIG. 5D) and it provides very high resistance, which results in nearly zero conductance of the Branch_{mod} (FIG. 5E). Besides the PVA, the other parameter that modulates the G_{branch_mod} is ΔV_{Ph}. The modulation effect of both the PVA and ΔV_{Ph} is presented in FIG. 6A. The current output (I_{OUT}) of the pixel is linearly proportional to G_{branch_mod}. In FIG. 6B, the PVA and ΔV_{Ph} values are multiplied, the products are normalized, and they are plotted as a two-dimensional (2D) color map. The pixel circuit was then simulated for all the PVA and ΔV_{Ph} combinations and the I_{OUT} was calculated. In FIG. 6C, another 2D color map is plotted in order to show the normalized calculated currents. FIG. 6C approximately matches FIG. 6B, indicating that the output current of the pixel circuit effectively approximates the result of a multiplication operation between PVA and ΔV_{Ph}. Furthermore, to observe the errors between the true mathematical products and the pixel-generated approximated products (pixel currents), the absolute difference between the normalized mathematical product and the normalized pixel-generated approximated product is plotted, as shown in FIG. 6D. The mean and standard deviation of these errors are 0.13 and 0.07, respectively. The Pearson correlation between the true product and the pixel-generated approximated product was calculated, which is 0.93, indicating a suitable linear relationship. The error is higher in the high ΔV_{Ph} region, which was not unexpected due to the non-linear behavior of the transistors. Accuracy can be improved by discarding higher ΔV_{Ph} values; however, this comes at the cost of reduced dynamic range in the image sensor. Therefore, a trade-off exists between multiplication accuracy and dynamic range, which can be adjusted based on the specific requirements of the application. Since the first layer of a CNN primarily extracts low-level features, it may be tolerant to such approximations, making it well-suited for analog or in-pixel computation even in the presence of moderate error.

### Accumulation

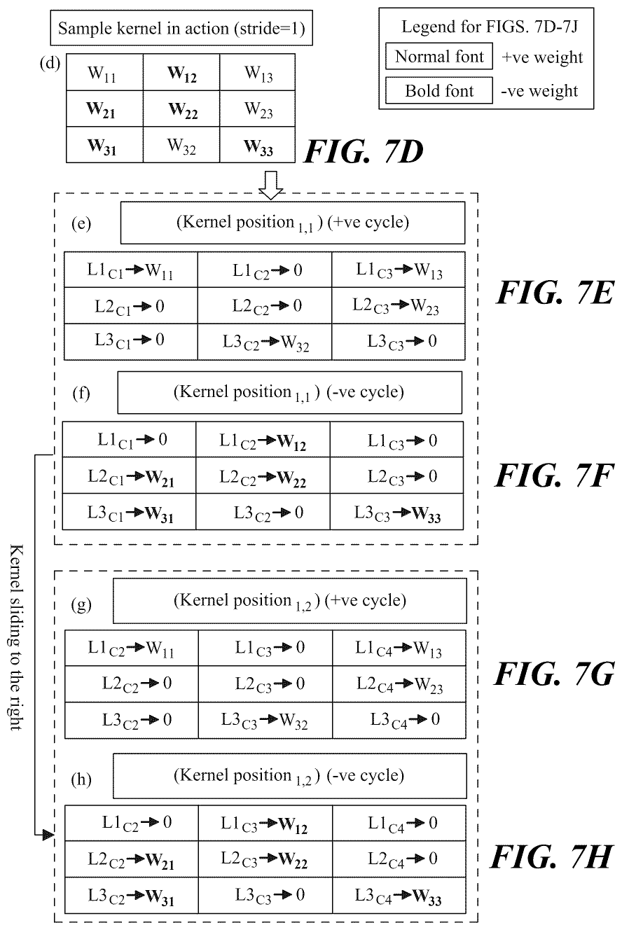

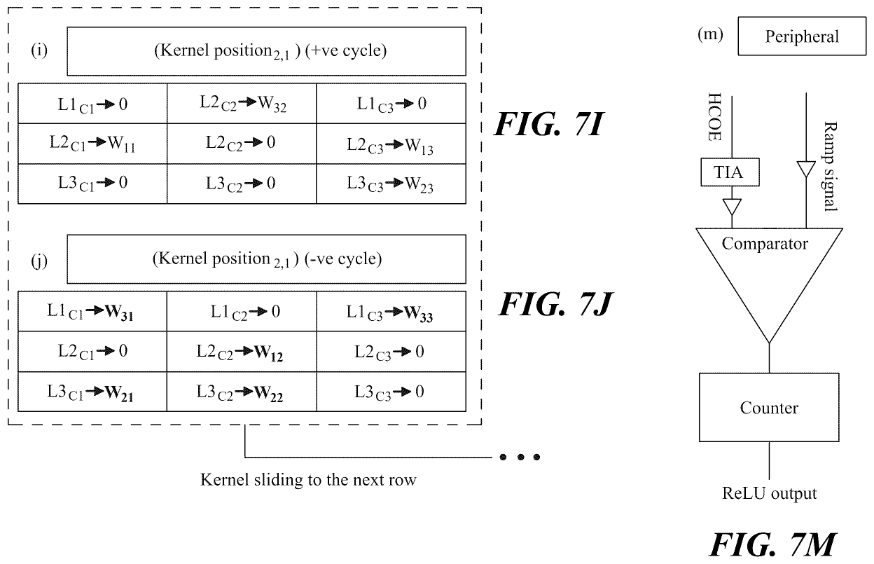

The image sensor pixel array 20 utilizing the in-sensor MAC pixel sensor circuit assembly 10 was simulated in HSPICE, in which all the pixels in a column 30 share an output line 32, as shown in FIG. 7A. The image sensor pixel array 20 has a multitude of columns 30. The column currents were aggregated at a node (NA). According to Kirchhoff's current law, the column currents represent the sum of all the pixel output currents in a column, and the current at NA represents the sum of all column currents, thus accumulation is achieved. This accumulation property was a reason, per an embodiment, for adopting a current-mode pixel design in the architecture of the pixel array 20 and in-sensor MAC pixel sensor circuit assembly 10, as all pixel outputs in a column are connected in parallel (i.e., exhibit a parallel arrangement), making current summation the most straightforward way to realize accumulation. All the pixels in a row share the V_{DD}, RST, SEL, and GND lines. In each column, the 1^{st}, 4^{th}, 7^{th}, and so on pixel positions share L1; the 2^{nd}, 5^{th}, 8^{th}, and so on share L2; and the 3^{rd}, 6^{th}, 9^{th}, and so on share L3, through which the gate voltages are supplied to the X_{FE}. The simplified conductance model for a column is shown in FIG. 7B. Here, each line represents the conductance model of the Branch_{mod} of the corresponding pixel, where G1_{XFE} and G1_{XP} are the conductances of the X_{FE} and X_{P}, and G_{const} represents other transistors in the branch. To use this array as a first layer of a CNN, ΔV_{Ph} is used as the input and PVA as the weights. A justification, per an embodiment, to use ΔV_{Ph} as the input is: according to the photodiode equation (ΔV_{Ph}/ΔT=I_{PD}/C_{PD}), ΔV_{Ph} is linearly proportional to the photocurrent I_{PD} (where the intrinsic capacitance of the photodiode or C_{PD} is constant, and the light integration time ΔT is maintained fixed). And I_{PD} is also linearly proportional to the photon flux density.

The pixel array 20 can handle a 3×3 kernel. This kernel size was selected, according to this embodiment, because it is the most effective and most commonly used; the kernel size can be modified in other embodiments. For a given 3×3 kernel position, the procedure for activating the corresponding pixels and deactivating the others is shown in FIG. 7C. The three corresponding rows for a kernel position are activated by setting the SEL signal high (which turns on the selector transistor 24), while for all the remaining rows, the SEL signal is set to 0 V. The columns that do not correspond to the active kernel position are deactivated by turning off the FeFETs 14 in those columns. The top-left pixel is denoted as (1,1). By “kernel position (1,1),” it is meant that the top-left corner of the kernel is aligned with pixel (1,1). The kernel then slides to the right with stride=1, and after completing the first row, it moves to kernel position (2,1). Now, the convolution operation is described for a certain kernel position using the example kernel shown in FIG. 7D. This kernel contains both positive and negative weights. For this kernel position, it is computed: Sum₁₁=/I₁₁W₁₁−I₁₂W₁₂+I₁₃W₁₃−I₂₁W₂₁−I₂₂W₂₂+I₂₃W₂₃−I₃₁W₃₁+I₃₂W₃₂−I₃₃W₃₃ (where I and W are the inputs and weights, respectively). This can be written as: Sum₁₁=(I₁₁W₁₁+I₁₃W₁₃+I₂₃W₂₃+I₃₂W₃₂)−(I₁₂W₁₂+I₂₁W₂₁+I₂₂W₂₂+I₃₁W₃₁+I₃₃W₃₃). Thus, the convolution is divided into two cycles: a positive cycle and a negative cycle.

Positive Cycle. In this embodiment, only the positive weight positions are activated in the positive cycle, while the negative weight positions are deactivated by turning off their X_{FE} transistors (i.e., FeFET 14). This is why each column has three separate X_{FE} gate lines so that each of the three X_{FE} transistors 14 in the active kernel position can be accessed individually. For example, in the first column, W₁₁ is sent through L1_{C1} (the pixel operates through the AWC as described above), while 0 V is sent to the other two pixels in that column (connected to L2_{C1} and L3_{C1}), since these correspond to negative weight positions (and operate through the IWC). The other pixels in the column that are also connected to L1_{C1} do receive the weight signal, but since their SEL signals are low, they remain deactivated and contribute nearly zero current. The same procedure is followed for the other two columns, as tabulated in FIG. 7E. At the end of the positive cycle, the summation of the column currents represents the positive half-convolution output element (HCOE), which is sent to the peripheral circuit shown in FIG. 7M. This peripheral circuit performs digital correlated double sampling (CDS). CDS is a well-established technique in conventional pixel sensors for noise cancellation. The HCOE passes through a transimpedance amplifier (TIA), is digitized by a comparator, and an 8-bit counter. During the positive cycle, the counter increments (up-count).

Negative Cycle. In this embodiment, the same method is applied, except that weights are supplied to the negative weight positions while the positive weight positions are deactivated (FIG. 7F). During this cycle, the counter decrements (down-count). The final counter value is the difference between the up-count and the down-count. If the down-count exceeds the up-count, the counter saturates at zero, thereby implementing the ReLU function.

After completing the first convolution output element, the kernel slides to the next position, (1,2). The weight assignments for L1, L2, and L3 are shown in FIG. 7G and FIG. 7H. The kernel continues sliding until the first row is complete, after which it proceeds to the next row at kernel position (2,1). At this position, the weight assignment sequence changes, because the first pixel (2,1) is connected to L2; thus, W₁₁ is supplied through L2, W₂₁ through L3, and so on (FIGS. 7I and 7J. After the kernel slides through all positions in the frame, the activation map is obtained, which is then forwarded to the next layer.

### Layout & A Convolution Output Element Generation

To estimate the pixel pitch of the proposed array, per this embodiment, the layout was implemented in Cadence Virtuoso using a 45-nm CMOS PDK. FIG. 7K and FIG. 7L show an embodiment of a tiled region of the array and an embodiment of a single-pixel layout (i.e., the in-sensor MAC pixel sensor circuit assembly 10), respectively. Pixel pitch was measured as the center-to-center distance between adjacent pixels in both the horizontal and vertical directions. The active photodiode measures 1.10 μm×1.12 μm. A summary of the extracted results from the layout is provided in Table I; still, other embodiments can yield other results.

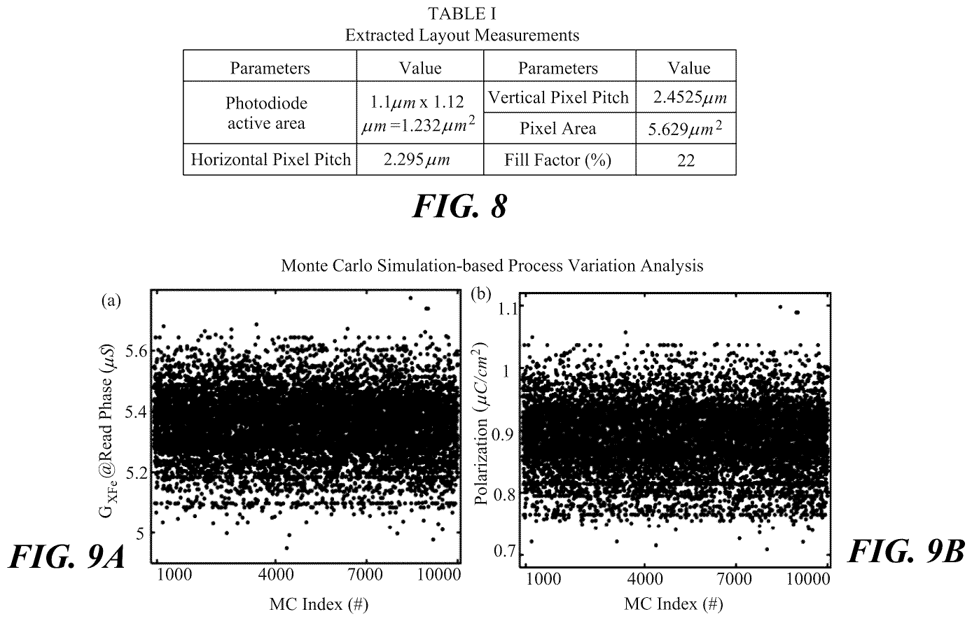

A sample result for one convolution output element for a certain kernel position according to this embodiment is shown in Table II of FIG. 10; still, other embodiments can yield other results. The circuit-generated total for the positive HCOE can be expressed as Sumₚₒₛ=true MAC result+Σpositive error during multiplication-Σnegative error during multiplication+Σleakage from the deactivated pixels+quantization error. Similarly, for the negative HCOE, Sum_{neg} also has same types of error components. The final result is Sum=Sumₚₒₛ−Sum_{neg}, so the common-mode offsets and matched gain errors largely cancel between the positive and negative cycles. Uncorrelated noise and asymmetric terms produce the residual error observed in Table II.

### Process Variation

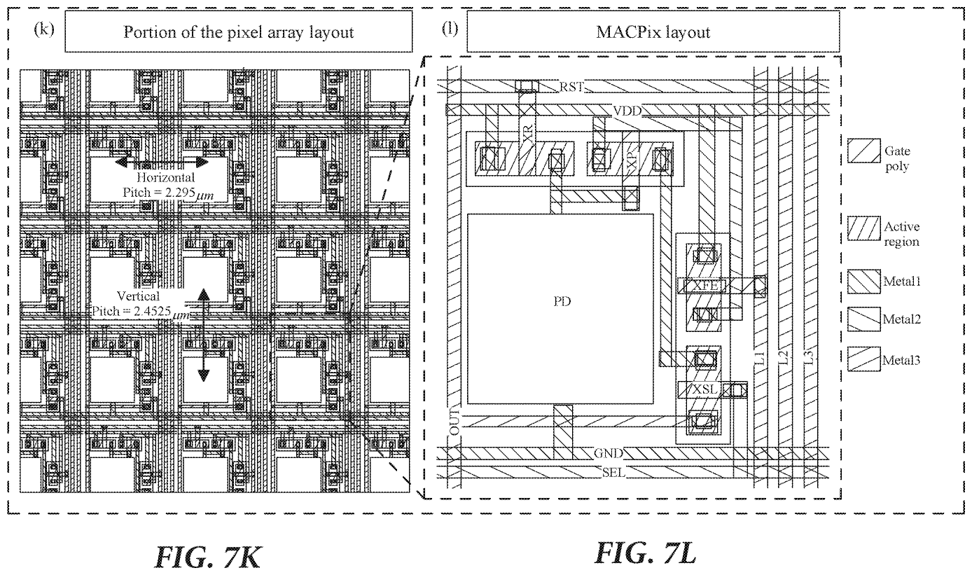

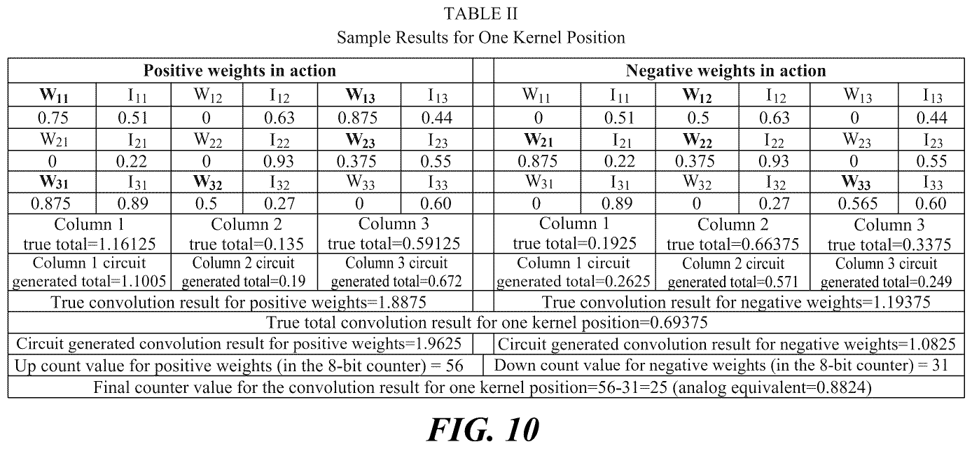

To mimic the pixel-to-pixel process variation and noise introduced by the FeFET 14, a Monte Carlo simulation was performed of 10,000 points, varying different parameters (FeCap thickness, threshold voltage deviation of X_{FE} and X_{P}) according to a Gaussian distribution (as shown in Table III in FIG. 11). The main effect of post-crystallization FE/DE phase mixing can be treated as an effective scaling and spread of the remanent polarization. Accordingly, in the Monte-Carlo FE/DE fluctuation was modeled implicitly by using a lumped FeCap thickness variation of +9%, chosen to conservatively cover both process thickness spread and FE/DE mixing in the sub-percolation regime reported in the literature. This keeps the model minimal while still capturing the dominant array-level sensitivity. The effects of variation on the conductance and remnant polarizations of the FeFET 14 are illustrated in FIG. 9A and FIG. 9B. The statistics are listed in Table III.

### Application-Level Analysis and Benchmarking

To evaluate the effect of hardware at the light-weight application level, a CNN was set up and trained on two datasets: MNIST and USPS. Then, using HSPICE, the test images (converted into voltage values) were passed through the pixel array 20 along with the pretrained first-layer weights, and the corresponding activation maps were obtained of the first convolutional layer. To mimic pixel-to-pixel process variation, deviated FeCap thicknesses and threshold voltages of the X_{FE} and X_{P} devices were assigned randomly to each pixel in the array, according to the distributions listed in Table III. Consequently, the activation maps obtained from HSPICE contain both the errors introduced by process variations and the error sources discussed above. These hardware-generated activation maps were then fed into the second layer of the CNN, and the rest of the network is executed in software, completing the full CNN inference.

Using this flow, it was observed that the baseline software inference on MNIST achieved an accuracy of 98.48%, whereas the end-to-end inference the hardware-generated activation maps yielded 91.99%. For the USPS dataset, the baseline software inference achieved an accuracy of 90.7%, while the corresponding end-to-end inference with hardware-generated activation maps achieved 86.8%. This corresponds to an absolute accuracy degradation of 6.49% for MNIST and 3.9% for USPS, reflecting the combined impact of process variation, device non-idealities, and analog compute inaccuracies (including disturb effects) within the pixel array 20. In the pixel array 20, the inclusion of variation effects together with device-level non-idealities leads to somewhat higher degradation, but provides a more comprehensive estimate of end-to-end performance. At the same time, the pixel array 20 achieves a smaller pixel pitch and higher energy efficiency (TOp/s/W), highlighting the compactness and efficiency of the architecture at the cost of a modest increase in application-level error.

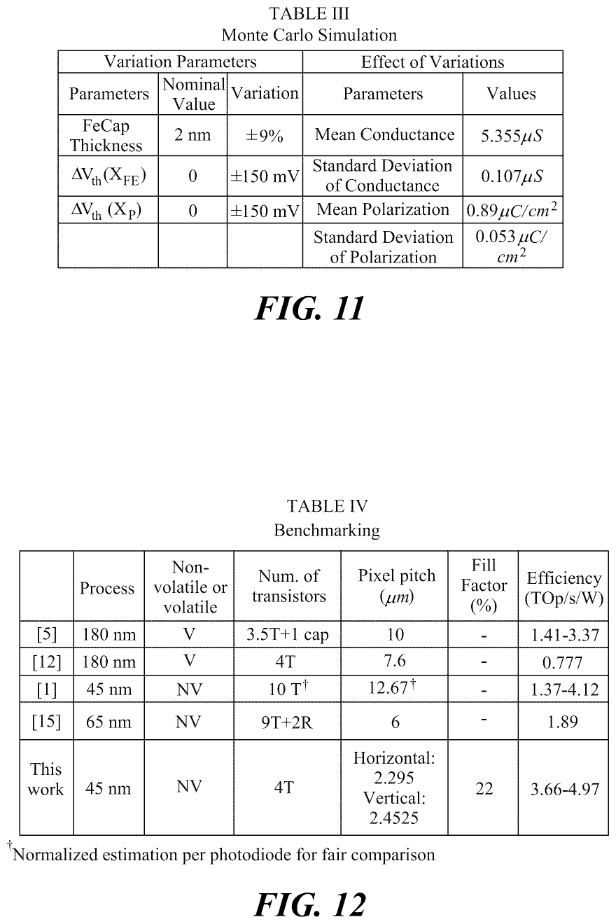

To benchmark the pixel array 20 architecture, a comparative analysis is presented in Table IV of FIG. 12, providing key parameters from other past pixel designs that have been proposed for implementing the first layer of CNN. The benchmarking shows a distinction between prior designs and the pixel array 20 and in-sensor MAC pixel sensor circuit assembly 10 (denoted “This work” in the table). Earlier volatile approaches required larger transistor budgets or additional capacitors, which constrained pixel scalability and imposed higher dynamic power overheads. Non-volatile designs addressed retention but often paid the price in circuit complexity and reduced pixel density. In contrast, the pixel array 20 and in-sensor MAC pixel sensor circuit assembly 10 achieves non-volatile weight storage with only four transistors per pixel, striking a balance between compactness and computational capability. While many in-pixel processing works primarily emphasize computational performance, detailed optical metrics such as fill factor are less frequently discussed, since the integration of processing elements naturally introduces trade-offs with photodiode area. By reporting a fill factor of 22%, the pixel array 20 and in-sensor MAC pixel sensor circuit assembly 10 acknowledges this trade-off and illustrates a practical balance between sensing and computing. Taken together, this comparison shows how the pixel array 20 and in-sensor MAC pixel sensor circuit assembly 10 architecture advances in-sensor computing by combining compact pixel design, intrinsic non-volatility, and array-level MAC functionality.

In summary, this embodiment of the pixel array 20 and in-sensor MAC pixel sensor circuit assembly 10 exhibits a compact and energy-efficient FeFET-based pixel architecture that enables in-sensor multiply-and-accumulate (MAC) operations by leveraging multi-domain polarization states. Simulation results demonstrate that the pixel output current closely approximates the mathematical product of input and weight, achieving a Pearson correlation of 0.93 with a mean error of 0.13 and a standard deviation of 0.07. Full MAC functionality is achieved within the image sensor array using 45 nm process technology, with a compact pixel pitch, making the design suitable for efficient edge AI applications, among many other possible applications. The pixel array 20 and in-sensor MAC pixel sensor circuit assembly 10 can enable compact, low-power, and high-performance vision systems for applications such as autonomous vehicles, smart cameras, and wearable AI, among many others.

In general, while a multitude of embodiments have been depicted and described with a multitude of components and steps in each embodiment, in alternative embodiments the components and steps of various embodiments could be intermixed, combined, and/or exchanged for one another. In other words, components described in connection with a particular embodiment are not necessarily exclusive to that particular embodiment.

As used herein, the terms “general” and “generally” and “substantially” are intended to account for the inherent degree of variance and imprecision that is often attributed to, and often accompanies, any design and manufacturing process, including engineering tolerances- and without deviation from the relevant functionality and intended outcome-such that mathematical precision and exactitude is not implied and, in some instances, is not possible. In other instances, the terms “general” and “generally” are intended to represent the inherent degree of uncertainty that is often attributed to any quantitative comparison, value, and measurement calculation, or other representation.

It is to be understood that the foregoing is a description of one or more aspects of the disclosure. The disclosure is not limited to the particular embodiment(s) disclosed herein, but rather is defined solely by the claims below. Furthermore, the statements contained in the foregoing description relate to particular embodiments and are not to be construed as limitations on the scope of the disclosure or on the definition of terms used in the claims, except where a term or phrase is expressly defined above. Various other embodiments and various changes and modifications to the disclosed embodiment(s) will become apparent to those skilled in the art. All such other embodiments, changes, and modifications are intended to come within the scope of the appended claims.

As used in this specification and claims, the terms “e.g.,” “for example,” “for instance,” “such as,” and “like,” and the verbs “comprising,” “having,” “including,” and their other verb forms, when used in conjunction with a listing of one or more components or other items, are each to be construed as open-ended, meaning that the listing is not to be considered as excluding other, additional components or items. Other terms are to be construed using their broadest reasonable meaning unless they are used in a context that requires a different interpretation.

What is claimed is:

1. An in-sensor multiply-and-accumulate (MAC) pixel sensor circuit assembly for an image sensor, the circuit assembly comprising:
a first transistor; and
a ferroelectric field-effect transistor (FeFET) electrically coupled with said first transistor;
wherein, amid use of the in-sensor multiply-and-accumulate pixel sensor circuit assembly, a programming voltage amplitude of said ferroelectric field-effect transistor is varied in order to effect various levels of remnant polarizations of said ferroelectric field-effect transistor and providing variations in conductance of said ferroelectric field-effect transistor.

2. The in-sensor multiply-and-accumulate (MAC) pixel sensor circuit assembly as set forth in claim 1, wherein, amid use of the in-sensor multiply-and-accumulate pixel sensor circuit assembly, multiply-and-accumulate operations of the in-sensor multiply-and-accumulate pixel sensor circuit assembly are executed wholly at the in-sensor multiply-and-accumulate pixel sensor circuit assembly.

3. The in-sensor multiply-and-accumulate (MAC) pixel sensor circuit assembly as set forth in claim 1, wherein said ferroelectric field-effect transistor is a five-terminal ferroelectric field-effect transistor, and one terminal of said five-terminal ferroelectric field-effect transistor transfers a polarization charge value of said five-terminal ferroelectric field-effect transistor during use of the in-sensor multiply-and-accumulate pixel sensor circuit assembly.

4. The in-sensor multiply-and-accumulate (MAC) pixel sensor circuit assembly as set forth in claim 1, further comprising a pixel selector transistor, and wherein said first transistor and said ferroelectric field-effect transistor are electrically coupled in series with respect to each other, and said first transistor and said pixel selector transistor are electrically coupled in series with respect to each other.

5. The in-sensor multiply-and-accumulate (MAC) pixel sensor circuit assembly as set forth in claim 1, wherein, amid use of the in-sensor multiply-and-accumulate pixel sensor circuit assembly, the in-sensor multiply-and-accumulate pixel sensor circuit assembly generates current as an output of the in-sensor multiply-and-accumulate pixel sensor circuit assembly.

6. The in-sensor multiply-and-accumulate (MAC) pixel sensor circuit assembly as set forth in claim 1, wherein, amid use of the in-sensor multiply-and-accumulate pixel sensor circuit assembly, during a reset phase of an active weight cycle of the in-sensor multiply-and-accumulate pixel sensor circuit assembly, a negative gate pulse is applied to said ferroelectric field-effect transistor in order to reset said ferroelectric field-effect transistor, and subsequently a positive gate pulse is applied to said ferroelectric field-effect transistor in order to set a polarization amount of said ferroelectric field-effect transistor.

7. The in-sensor multiply-and-accumulate (MAC) pixel sensor circuit assembly as set forth in claim 6, wherein a programming voltage amplitude to set said polarization amount of said ferroelectric field-effect transistor is greater than a supply voltage of said reset phase.

8. The in-sensor multiply-and-accumulate (MAC) pixel sensor circuit assembly as set forth in claim 6, further comprising a pixel selector transistor electrically coupled with said first transistor, and wherein, amid use of the in-sensor multiply-and-accumulate pixel sensor circuit assembly, during a light integration phase of said active weight cycle of the in-sensor multiply-and-accumulate pixel sensor circuit assembly, said ferroelectric field-effect transistor is activated and said pixel selector transistor is activated.

9. The in-sensor multiply-and-accumulate (MAC) pixel sensor circuit assembly as set forth in claim 1, wherein, amid use of the in-sensor multiply-and-accumulate pixel sensor circuit assembly, during an inactive weight cycle of the in-sensor multiply-and-accumulate pixel sensor circuit assembly, said ferroelectric field-effect transistor is deactivated.

10. An image sensor pixel array comprising a first plurality of in-sensor multiply-and-accumulate pixel sensor circuit assemblies as set forth in claim 1, wherein a column of said image sensor pixel array includes a second plurality of in-sensor multiply-and-accumulate pixel sensor circuit assemblies of said first plurality of in-sensor multiply-and-accumulate pixel sensor circuit assemblies, said second plurality of in-sensor multiply-and-accumulate pixel sensor circuit assemblies of said column exhibiting a parallel arrangement with respect to one another and sharing an output line.

11. The image sensor pixel array as set forth in claim 10, wherein outputs of all of said second plurality of in-sensor multiply-and-accumulate pixel sensor circuit assemblies of said column are current outputs, and a current of said column is a sum of all current outputs of said second plurality of in-sensor multiply-and-accumulate pixel sensor circuit assemblies of said column.

12. An image sensor comprising a plurality of pixels, at least some of said plurality of pixels having a dedicated in-sensor multiply-and-accumulate (MAC) pixel sensor circuit assembly as set forth in claim 1 residing therein.

13. An in-sensor multiply-and-accumulate (MAC) pixel sensor circuit assembly for an image sensor, the circuit assembly comprising:
a first transistor;
a ferroelectric field-effect transistor (FeFET) electrically coupled with said first transistor; and
a pixel selector transistor electrically coupled with said first transistor;
wherein, amid use of the in-sensor multiply-and-accumulate pixel sensor circuit assembly, multiply-and-accumulate operations of the in-sensor multiply-and-accumulate pixel sensor circuit assembly are executed wholly at the in-sensor multiply-and-accumulate pixel sensor circuit assembly;
wherein, amid use of the in-sensor multiply-and-accumulate pixel sensor circuit assembly, during a reset phase of an active weight cycle of the in-sensor multiply-and-accumulate pixel sensor circuit assembly, a negative gate pulse is applied to said ferroelectric field-effect transistor in order to reset said ferroelectric field-effect transistor, and subsequently a positive gate pulse is applied to said ferroelectric field-effect transistor in order to set a polarization amount of said ferroelectric field-effect transistor; and
wherein, amid use of the in-sensor multiply-and-accumulate pixel sensor circuit assembly, during an inactive weight cycle of the in-sensor multiply-and-accumulate pixel sensor circuit assembly, said ferroelectric field-effect transistor is deactivated.

14. The in-sensor multiply-and-accumulate (MAC) pixel sensor circuit assembly as set forth in claim 13, wherein a programming voltage amplitude to set said polarization amount of said ferroelectric field-effect transistor is greater than a supply voltage of said reset phase.

15. The in-sensor multiply-and-accumulate (MAC) pixel sensor circuit assembly as set forth in claim 13, wherein, amid use of the in-sensor multiply-and-accumulate pixel sensor circuit assembly, during a light integration phase of said active weight cycle of the in-sensor multiply-and-accumulate pixel sensor circuit assembly, said ferroelectric field-effect transistor is activated and said pixel selector transistor is activated.

16. An image sensor pixel array comprising a first plurality of in-sensor multiply-and-accumulate pixel sensor circuit assemblies as set forth in claim 13, wherein a column of said image sensor pixel array includes a second plurality of in-sensor multiply-and-accumulate pixel sensor circuit assemblies of said first plurality of in-sensor multiply-and-accumulate pixel sensor circuit assemblies, said second plurality of in-sensor multiply-and-accumulate pixel sensor circuit assemblies of said column exhibiting sharing an output line.

17. The image sensor pixel array as set forth in claim 16, wherein outputs of all of said second plurality of in-sensor multiply-and-accumulate pixel sensor circuit assemblies of said column are current outputs, and a current of said column is a sum of all current outputs of said second plurality of in-sensor multiply-and-accumulate pixel sensor circuit assemblies of said column.

18. An image sensor comprising the image sensor pixel array as set forth in claim 16.

19. An in-sensor multiply-and-accumulate (MAC) pixel sensor circuit assembly for an image sensor, the circuit assembly comprising:
a first transistor;
a ferroelectric field-effect transistor (FeFET) electrically coupled with said first transistor, wherein a terminal of said ferroelectric field-effect transistor transfers a polarization charge value of said ferroelectric field-effect transistor during use of the in-sensor multiply-and-accumulate pixel sensor circuit assembly; and
a pixel selector transistor electrically coupled with said first transistor;
wherein, amid use of the in-sensor multiply-and-accumulate pixel sensor circuit assembly, multiply-and-accumulate operations of the in-sensor multiply-and-accumulate pixel sensor circuit assembly are executed wholly at the in-sensor multiply-and-accumulate pixel sensor circuit assembly; and
wherein, amid use of the in-sensor multiply-and-accumulate pixel sensor circuit assembly, a programming voltage amplitude of said ferroelectric field-effect transistor is varied in order to effect various levels of remnant polarizations of said ferroelectric field-effect transistor and providing variations in conductance of said ferroelectric field-effect transistor.

20. An image sensor pixel array comprising a first plurality of in-sensor multiply-and-accumulate pixel sensor circuit assemblies as set forth in claim 19,
wherein a column of said image sensor pixel array includes a second plurality of in-sensor multiply-and-accumulate pixel sensor circuit assemblies of said first plurality of in-sensor multiply-and-accumulate pixel sensor circuit assemblies, said second plurality of in-sensor multiply-and-accumulate pixel sensor circuit assemblies of said column exhibiting sharing an output line, and wherein outputs of all of said second plurality of in-sensor multiply-and-accumulate pixel sensor circuit assemblies of said column are current outputs, and a current of said column is a sum of all current outputs of said second plurality of in-sensor multiply-and-accumulate pixel sensor circuit assemblies of said column.
